(19) United States
(12) Patent Application Publication
(10) Pub. No.: US 2015/0048233 A1
(43) Pub. Date: Feb. 19, 2015

(54) PORTABLE ELECTRONIC SUPPORT DEVICES

(71) Applicant: Matthew Richard Dumas, Indianapolis, IN (US)

(72) Inventor: Matthew Richard Dumas, Indianapolis, IN (US)

(21) Appl. No.: 14/207,441

(22) Filed: Mar. 12, 2014

Related U.S. Application Data
(60) Provisional application No. 61/779,018, filed on Mar. 13, 2013.

(51) Int. Cl. H05K 5/02; F16M 11/24; H05K 5/00; F16M 11/20

(52) U.S. Cl. CPC H05K 5/0204; F16M 11/2014; F16M 11/242; H05K 5/0086
USPC 248/550; 248/121; 248/125.7; 248/125.8

(57) ABSTRACT

Portable electronic device stands for use with tablet computers, cellular phones, or other portable electronic devices are disclosed. One stand embodiment may include a base assembly which may include a plurality of retractable legs, a vertical axis assembly coupled to the base assembly and configured to store the base within, a horizontal axis assembly coupled to the vertical axis assembly, and an electronic device coupling assembly for removably attaching the electronic device to the stand.

### CROSS-REFERENCE TO RELATED APPLICATIONS

This application claims priority under 35 U.S.C. §119(e) to U.S. Provisional Patent Application Ser. No. 61/779,018 entitled PORTABLE ELECTRONIC SUPPORT DEVICES, filed Mar. 12, 2013, the content of which is incorporated by reference herein in its entirety.

### FIELD

This disclosure is directed generally to accessories for use with portable electronics, such as tablets, cellular phones, compact computers, televisions, and the like. More particularly, but not exclusively, the disclosure relates to a lightweight and portable adjustable support stand for use with such devices to allow a user to quickly set up and adjust positioning of the devices on desks, tables, or other surfaces.

### BACKGROUND

As portable electronic devices continue to proliferate, more people are using portable devices such as smart phones, tablet computers, and other devices for functions that were previously done with a computer or other audiovisual device. At the same time, these portable devices typically do not include stands or other apparatus for mounting or positioning the devices during use. Tablet device covers have become available, and some have folding cover elements and hinges, however, these do not allow a user to readily adjust the position and/or orientation devices for use. Moreover, larger mounting apparatus has become available for mounting televisions or computer monitors to walls or other surfaces, however, these are typically large, heavy, and often must be fixedly attached to the wall or other surface.

Accordingly, there is a need in the art to address the above as well as other problems.

### SUMMARY

For example, the disclosure relates to a portable electronics device stand. The stand may include, for example, a device coupling element. The stand may further include a horizontal axis support element coupled to the device coupling element. The stand may further include a vertical axis support element. The stand may further include a support element connection bracket coupled between the horizontal axis support element and the vertical axis support element. The stand may further include a base coupled to the vertical axis support element.

The device coupling element may, for example, be configured to rotate an attached device about a central axis. The device coupling element may include a suction cup or other suction element to attach the electronic device to the stand. The device coupling element includes a threaded element to attach the device. The threaded element may be a machine screw or other screw-type element. The machine screw may be screwed into a corresponding threaded mount on the electronic device. The horizontal axis support element, the vertical axis support element, or both support elements may include one or more internal threaded holes. The horizontal axis support element may include a threaded hole and wherein the support element connection bracket is attached to the horizontal axis support element. A machine screw may be screwed into the threaded hole. The vertical axis support element may include a threaded hole. The support element connection bracket may be attached to the vertical axis support element with a machine screw that may be screwed into the threaded hole. The vertical axis support element may be omitted and the horizontal axis support element may be coupled directly to a base or tripod element.

The horizontal support element, vertical support element, or both support elements may, for example, be configured in a substantially cylindrical shape. One or more of the support elements may be configured with an alternate cross-section in whole or part, such as a square, rectangular, triangular, or oval cross-section rather than a circular/cylindrical cross-section. The horizontal support element, vertical support element, or both support elements may include a textured or other grippable surface, such as a soft rubber, foam, or other grippable surface on whole or part of the element to facilitate gripping by a user.

The support element connection bracket may, for example, be formed in substantially an L-shaped configuration. The support element connection bracket may alternately be formed in an S-shaped or other angled or curve-shaped configuration to enhance support and balancing of the stand with the device installed. The vertical axis support element may include an internal threaded hole. The base may be attached to the vertical axis support element using a corresponding threaded element screwed into the threaded hole.

The base may, for example, be a tripod or four or more leg structure. The tripod may have collapsing or folding legs. The legs may be concentric collapsing tubes. The stand may be configured so that the legs collapse and slide into another element of the stand, such as the vertical support element. The base may include a weight for supporting a predefined device weight when the device is attached to the electronics device coupling element. The tripod may include a plurality of collapsible legs and at least a lower portion of the collapsible legs may be weighted with a high density material to lower the center of gravity of the stand.

The device coupling element may, for example, include an active material suction cup. A portion of the active material suction cup may comprise the active material, which may be movable to provide suction. The device may further include an activation device. The activation device may include an electronic circuit for controlling movement of the active material to apply or release suction. The active material may be a piezoelectric material or other active material. The stand may further include a suction sensor to provide an output responsive to a suction condition. The suction condition may be a suction failure or pressure increase. The suction condition may be an acceptable amount of suction to maintain support of the device. The suction condition may be no suction or an over-suction condition.

The device coupling element may, for example, include a slotted coupling mechanism. The device coupling element includes a hook and loop material. The stand may further include a support mechanism for an additional device. The support mechanism for the additional device may include a suction cup, slotted coupling mechanism, hook and loop material, screwable connection, or other connection mechanism. The support mechanism may further include a bracket assembly to couple the additional device to the stand.

The stand may further include a counterweight assembly. The counterweight assembly may be in a spherical shape or other shape. The counterweight assembly may be adjustably movable in, out, up, or down to adjust counterweighting. The counterweight may be adjustable using sliding, hinged, or other movable mechanisms.

The may further including an adjustable horizontal element coupled between the horizontal axis support element and electronic device coupling element. The adjustable horizontal element may be a two or more section telescoping collapsible assembly or a sliding or otherwise movable assembly. The vertical axis support element may be omitted and the horizontal axis support element may be coupled directly to a base or tripod element.

Various additional aspects and details are further described below in conjunction with the appended Drawings.

### BRIEF DESCRIPTION OF THE DRAWINGS

FIG. 1 illustrates one embodiment of a portable electronic device support stand in accordance with certain aspects;

FIG. 2A illustrates additional details of the support stand embodiment of FIG. 1;

FIGS. 2B & 2C illustrate additional details of the support stand embodiment of FIG. 1, where the leg structure is foldable to be retracted into the vertical support assembly;

FIG. 3 illustrates details of an embodiment of a horizontal axis support assembly as may be used on a stand such as the stand of FIG. 1;

FIG. 4 illustrates details of an embodiment of a device coupling assembly as may be used on a stand such as the stand of FIG. 1;

FIG. 5 illustrates details of an embodiment of a support assembly coupling bracket as may be used on a stand such as the stand of FIG. 1;

FIG. 6 illustrates details of an embodiment of a vertical axis support assembly as may be used on a stand such as the stand of FIG. 1;

FIG. 7 illustrates details of an alternate coupling assembly as may be used on a stand such as the stand of FIG. 1;

FIG. 8 illustrates details of an alternate embodiment of a portable electronic device support stand having a combination support assembly;

FIG. 9 illustrates details of an alternate embodiment of a portable electronic device support stand having a weighted base assembly;

FIGS. 10 and 11 illustrate details of an alternate coupling assembly including an active material;

FIG. 12 illustrates details of an alternate embodiment of a portable electronic device support stand including a counterweight assembly;

FIG. 13 illustrates details of an alternate embodiment of a portable electronic device support stand having a support assembly for a second device;

FIGS. 14A and 14B illustrate details of an alternate embodiment including a slotted coupling mechanism;

FIG. 15 illustrates details of an alternate embodiment of a portable electronic device support stand including a counterweight assembly with the vertical axis support assembly omitted; and

FIG. 16 illustrates details of an alternate embodiment of a portable electronic device support stand having a collapsible telescoping extension between the support assemblies and device attachment mechanism.

### DETAILED DESCRIPTION OF EMBODIMENTS

This disclosure is directed generally to accessories for use with portable electronics, such as tablets, cellular phones, compact computers, televisions, and the like. In one aspect, the disclosure relates to a lightweight and portable adjustable support stand for use with such devices to allow a user to quickly set up and adjust positioning of the devices on desks, tables, or other surfaces. Various embodiments of such stands or supports may be used to allow a user to quickly set up a temporary or permanent mount for a portable electronic device such as a tablet, smart phone, compact computer, or other portable electronic device. Adjustable assemblies may be included to allow for quick adjustment of the positioning of the electronic device is one or more axes of motion. In addition, embodiments of such stands may be configured to allow rapid assembly and disassembly, and further allow for compact storage of the stand and associated assemblies.

For example, the disclosure relates to a portable electronics device stand. The stand may include, for example, a device coupling element. The stand may further include a horizontal axis support element coupled to the device coupling element. The stand may further include a vertical axis support element. The stand may further include a support element connection bracket coupled between the horizontal axis support element and the vertical axis support element. The stand may further include a base coupled to the vertical axis support element.

The device coupling element may, for example, be configured to rotate an attached device about a central axis. The device coupling element may include a suction cup or other suction element to attach the electronic device to the stand. The device coupling element includes a threaded element to attach the device. The threaded element may be a machine screw or other screw-type element. The machine screw may be screwed into a corresponding threaded mount on the electronic device. The horizontal axis support element, the vertical axis support element, or both support elements may include one or more internal threaded holes. The horizontal axis support element may include a threaded hole and wherein the support element connection bracket is attached to the horizontal axis support element. A machine screw may be screwed into the threaded hole. The vertical axis support element may include a threaded hole. The support element connection bracket may be attached to the vertical axis support element with a machine screw that may be screwed into the threaded hole. The vertical axis support element may be omitted and the horizontal axis support element may be coupled directly to a base or tripod element.

The horizontal support element, vertical support element, or both support elements may, for example, be configured in a substantially cylindrical shape. One or more of the support elements may be configured with an alternate cross-section in whole or part, such as a square, rectangular, triangular, or oval cross-section rather than a circular/cylindrical cross-section. The horizontal support element, vertical support element, or both support elements may include a textured or other grippable surface, such as a soft rubber, foam, or other grippable surface on whole or part of the element to facilitate gripping by a user.

The support element connection bracket may, for example, be formed in substantially an L-shaped configuration. The support element connection bracket may alternately be formed in an S-shaped or other angled or curve-shaped configuration to enhance support and balancing of the stand with the device installed. The vertical axis support element may include an internal threaded hole. The base may be attached to the vertical axis support element using a corresponding threaded element screwed into the threaded hole.

The base may, for example, be a tripod or four or more leg structure. The tripod may have collapsing or folding legs. The legs may be concentric collapsing tubes. The stand may be configured so that the legs collapse and slide into another element of the stand, such as the vertical support element. The base may include a weight for supporting a predefined device weight when the device is attached to the electronics device coupling element. The tripod may include a plurality of collapsible legs and at least a lower portion of the collapsible legs may be weighted with a high density material to lower the center of gravity of the stand.

The device coupling element may, for example, include an active material suction cup. A portion of the active material suction cup may comprise the active material, which may be movable to provide suction. The device may further include an activation device. The activation device may include an electronic circuit for controlling movement of the active material to apply or release suction. The active material may be a piezoelectric material or other active material. The stand may further include a suction sensor to provide an output responsive to a suction condition. The suction condition may be a suction failure or pressure increase. The suction condition may be an acceptable amount of suction to maintain support of the device. The suction condition may be no suction or an over-suction condition.

The device coupling element may, for example, include a slotted coupling mechanism. The device coupling element includes a hook and loop material. The stand may further include a support mechanism for an additional device. The support mechanism for the additional device may include a suction cup, slotted coupling mechanism, hook and loop material, screwable connection, or other connection mechanism. The support mechanism may further include a bracket assembly to couple the additional device to the stand.

The stand may further include a counterweight assembly. The counterweight assembly may be in a spherical shape or other shape. The counterweight assembly may be adjustably movable in, out, up, or down to adjust counterweighting. The counterweight may be adjustable using sliding, hinged, or other movable mechanisms.

The may further including an adjustable horizontal element coupled between the horizontal axis support element and electronic device coupling element. The adjustable horizontal element may be a two or more section telescoping collapsible assembly or a sliding or otherwise movable assembly. The vertical axis support element may be omitted and the horizontal axis support element may be coupled directly to a base or tripod element.

Details herein may be combined in various embodiments with disclosures such as those of U.S. Pat. No. 7,226,026, issued Jun. 5, 2007, entitled SUCTION DEVICE, the content of which is incorporated by reference herein.

As used herein, the term “exemplary” means serving as an example, instance or illustration. Any aspect and/or embodiment described herein as “exemplary” is not necessarily to be construed as preferred or advantageous over other aspects and/or embodiments.

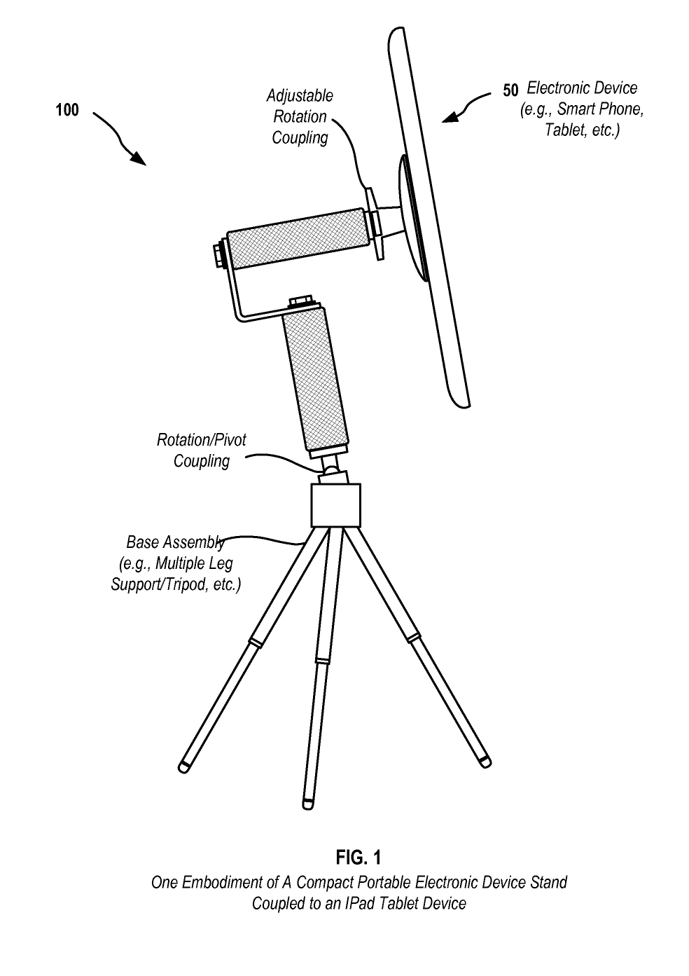

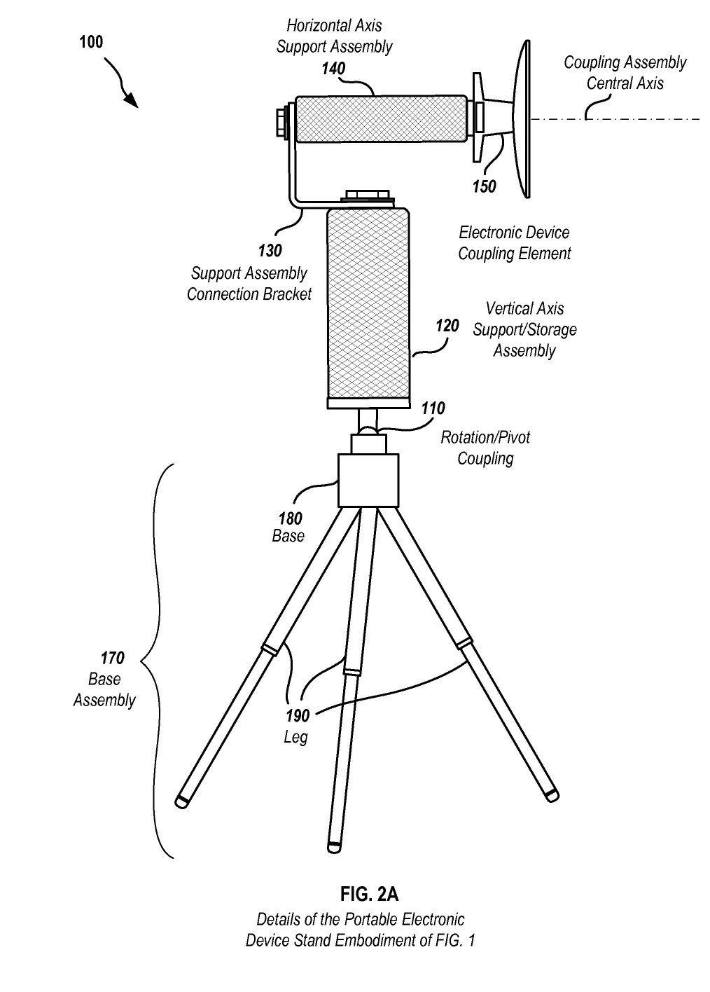

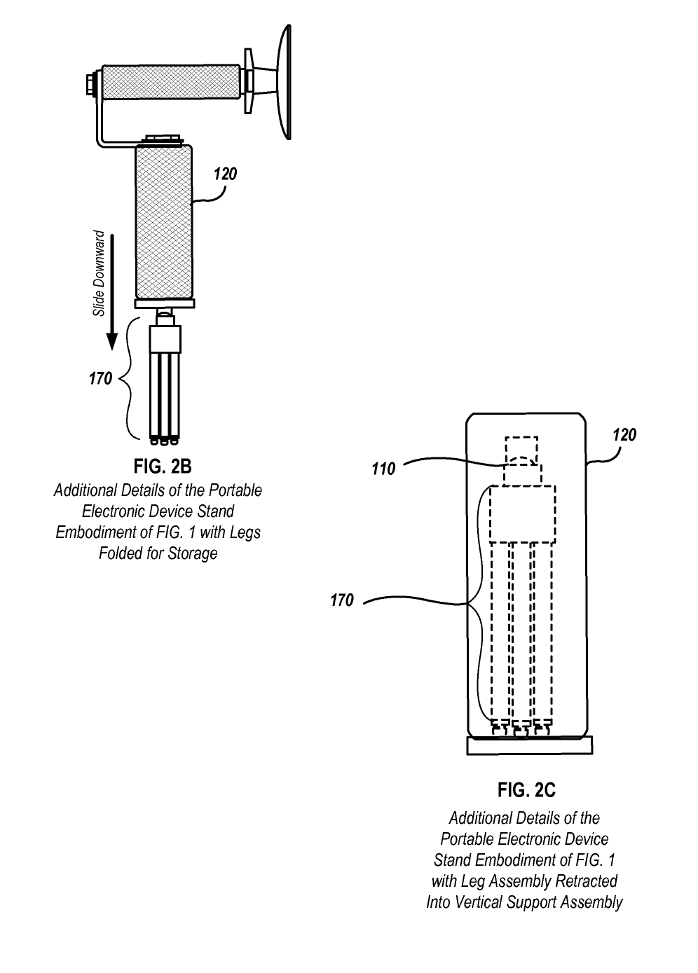

Referring to FIG. 1, an embodiment 100 of a portable adjustable support stand (also denoted herein as a “portable stand” or “stand” for brevity) that may be used to mount a portable electronic device 50 such as a tablet, smart phone, or other device, is illustrated. The stand embodiment 100 of FIG. 1 may include assemblies allowing a user to adjust the positioning of the electronic device is one or more axes of motion, such as height, angle of rotation about horizontal or vertical axes, as well as rotation.

A typical stand embodiment includes a base assembly, a vertical support assembly, a horizontal support assembly, and a coupling assembly to removably couple the electronic device to the stand.

FIG. 2A illustrates additional details of stand embodiment 100 of FIG. 1. As shown in FIG. 2, stand embodiment 100 includes a base assembly embodiment 170, which may comprise multiple legs 190 coupled to a base 180, which may include or be attached to a rotation/pivot coupling embodiment 110. The base assembly may be coupled to a vertical axis (relative to a normal upright orientation on the ground, a table or desk, etc.) support assembly embodiment 120, which may be further configured to store the base assembly in a retracted position as described subsequently with respect to FIGS. 2B & 2C.

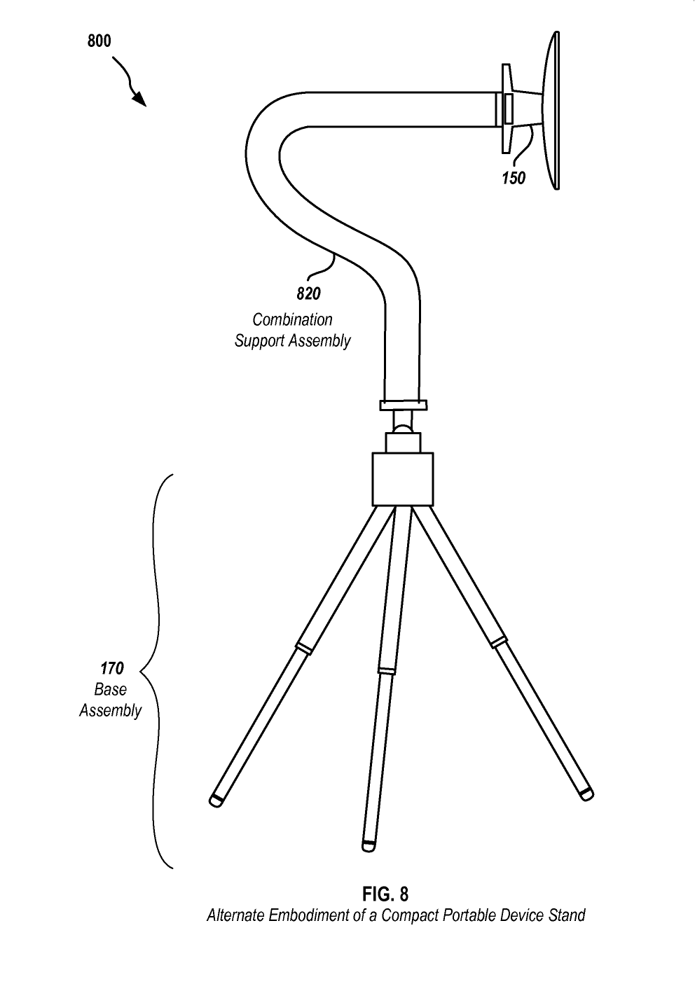

Vertical axis assembly embodiment 120 may be coupled to a horizontal axis support assembly embodiment 140 using an L-bracket or other connection bracket embodiment, such as L-bracket 130 as shown. In other embodiments, such as embodiment 800 as shown in FIG. 8, the vertical and horizontal support assemblies may be integral (as shown) and/or may be alternately configured (not shown) to couple the electronic device to the base assembly.

In an exemplary embodiment, the base assembly 170 may include a plurality of legs 190, which may be extendible, such as through use of concentric sliding leg elements or other extension mechanisms. The legs 190 may be flexibly coupled to the base 180, such as with a ball or other movable hinge assembly to allow the legs to be spread outward as shown during deployment, and then retracted for storage.

The vertical support assembly 120 may be configured with a hollow center to allow the base assembly to be stored or retracted into the vertical support assembly for storage and transportation. By allowing the legs and other base assembly elements to be stored within vertical support assembly 120, the stand may be compactly stored and transported, while also being assembled quickly for use.

Coupling assembly embodiment 150 may include an adjustable element for allowing rotation of the electronic device about the coupling assembly central axis as shown to allow a user to rotate the electronic device to a “landscape” or “portrait” orientation, or to other orientations as needed.

FIG. 2B illustrates details of the stand embodiment 100 where the base assembly 170 may be returned to a storage position with the legs moved inward and compacted in length. The vertical support assembly 120 may then be pushed downward (in the illustrated orientation), moving the base assembly 170 inside the vertical support assembly 120 as shown in FIG. 2C.

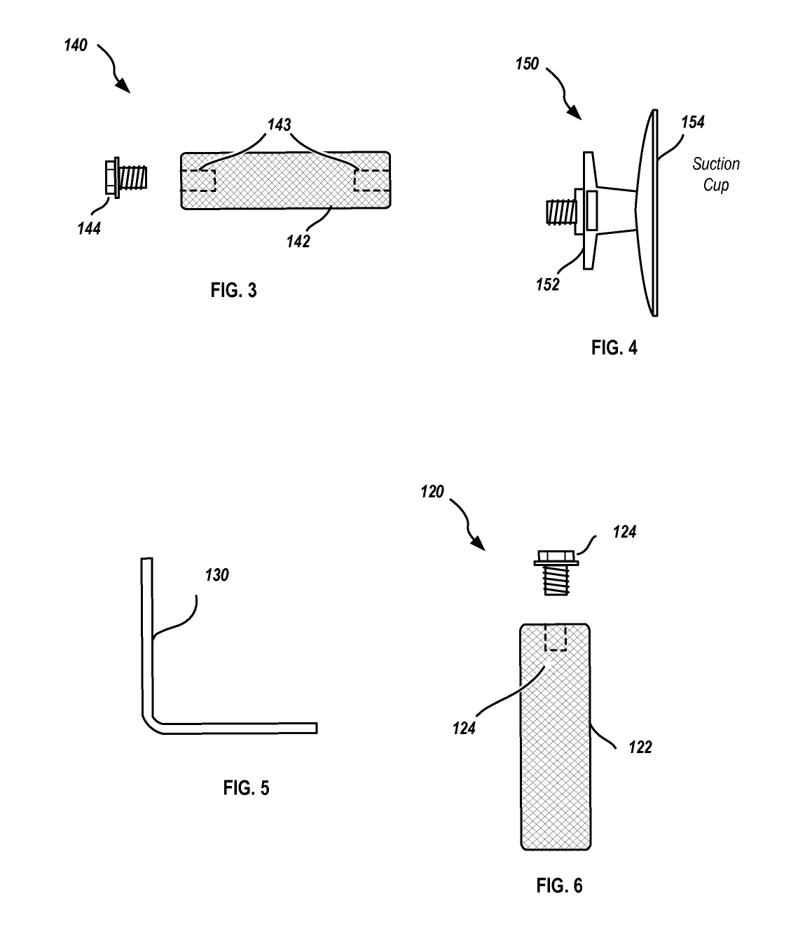

FIG. 3 illustrates additional details of the horizontal support assembly embodiment 140. Horizontal support assembly 140 may include a handle or housing 142, which may be in a cylindrical or other ergonomic shape and may include knurling or other surface features, such as a textured rubber outer surface, etc. Interior holes 143 may be threaded to allow mounting of the assembly 140 to a coupling bracket, such as bracket 130 as shown in FIG. 5, which may have holes or other mechanisms for attachment. FIG. 4 illustrates one embodiment of a coupling assembly 150, which may include a knob or handle-like element 152 to allow a user to rotate the electronics device relative to a central axis, along with a suction cup 154 to allow quick attachment and removal of the electronic device, such as is shown in FIG. 1.

FIG. 6 illustrates details of an embodiment of a vertical support assembly 120, which may include a handle or housing 122 with one or more holes 124 to allow mounting of the assembly 120 to a coupling bracket such as bracket 130, which may be done using screws 124 or other attachment mechanisms. As illustrated in FIG. 2C, the interior of assembly 120 may be hollow to allow the base assembly to retract therein.

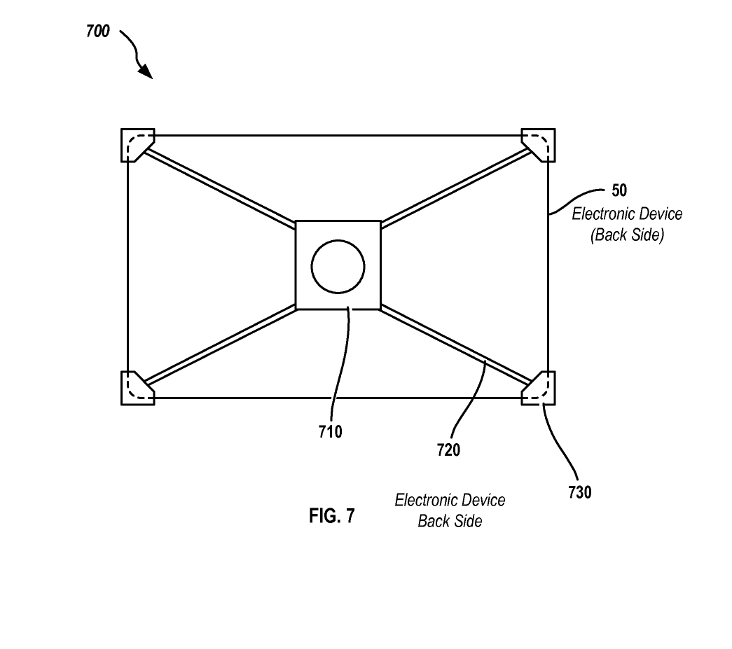

FIG. 7 illustrates details of an alternate embodiment 700 of a coupling assembly that may be used in place of the suction cup-based assembly embodiment 150 of FIG. 4. In this embodiment, one or more retention brackets 730 may be used to retain the electronic device 50 relative to a coupling base 710. tensioned cables 720 or other mechanisms may be used to hold the retention brackets to the base 710. These may be spring loaded or bungy-cord like cables or other cables or wires suitable for retaining the electronic device 50 relative to the base 710. Base 710 may further include a handle or knob (as shown in FIG. 4) or other mechanism to allow a user to rotate the electronic device on the stand, such as from a portrait to landscape orientation or to other orientations.

FIG. 8 illustrates details of another embodiment 800 of a portable electronic device stand in accordance with certain aspects. In this embodiment, the vertical and horizontal support assemblies may be replaced with a single combination assembly embodiment 820, which may be integral or may comprise two or more elements. In some embodiments, the lower end of assembly 820 may be hollow to allow the base assembly to retract within, similarly to the configuration shown in FIGS. 2B and 2C.

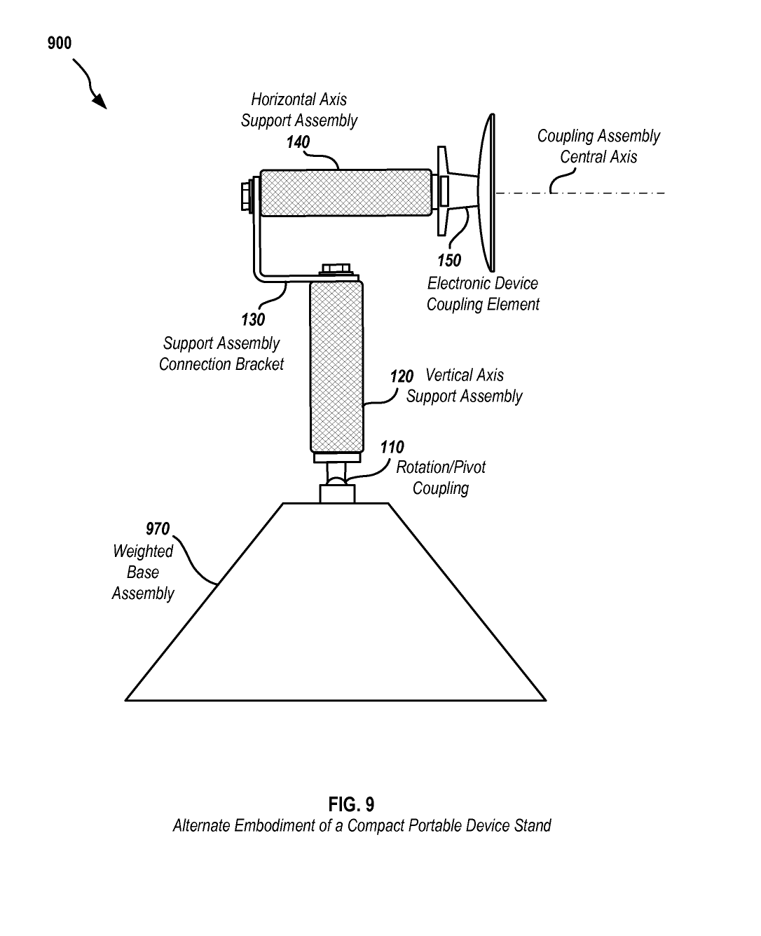

FIG. 9 illustrates details of yet another embodiment 900 of a portable electronic device stand in accordance with certain aspects. In this embodiment, the base assembly may include a weighted element, such as a block or slab of metallic material, rather than a leg configuration as shown in FIG. 1. The vertical and horizontal assemblies of FIG. 9 may be interchanged with the combination assembly of FIG. 8 in some embodiments, as may the coupling assembly 150 and coupling assembly 700 of FIG. 7.

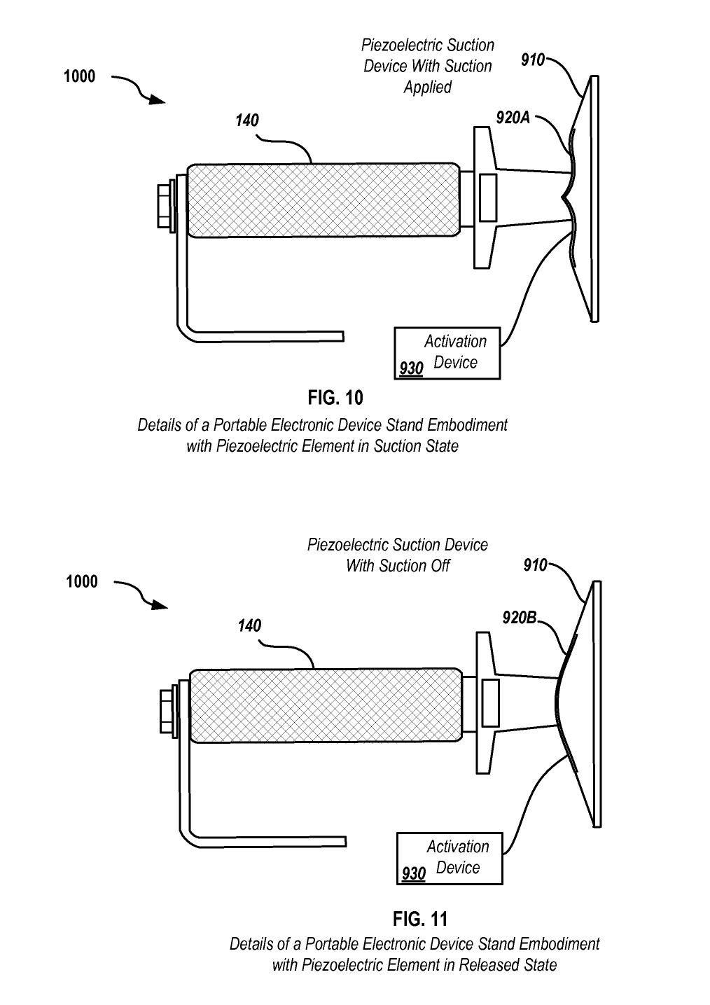

In some embodiments, suction applied to the electronic device may be implemented and controlled using electromagnetic or other electromechanical devices, such as active material devices using shape memory alloys, ferromagnetic shape memory alloys, shape memory polymers, piezoelectric materials, electroactive polymers, magnetoresitive polymers, and the like. For example, active material suction devices, such as are described in, for example, U.S. Pat. No. 8,096,537, entitled ACTIVE MATERIAL BASED SUCTION CUPS. One example embodiment of such a configuration is shown in FIGS. 10 and 11, which may be configured similarly to the device stand of FIG. 1 and/or other stands described herein but may further include active material elements such as piezoelectrics and the like. As shown i FIG. 10, a device stand 1000 may include an active suction element 910 as shown to provide suction between the stand and a coupled portable electronic device. This element may be configured, for example, similarly to the active suction devices described in the '537 patent, with an actively controlled movable element 920, which is shown in an applied suction state as 920A in FIG. 10 and in a released state as 920B in FIG. 11. An activation device or other control element 930 may include electronics to apply electrical signals to the movable element 920 to apply, release, and/or selectively control suction. Additional element, such as suction or pressure sensors and the like may be included in the suction cup or other pressurized elements to provide an indication, such as audibly or visually, that suction is being maintained and/or lost in situations where the cup is leaking or otherwise failing to maintain suction.

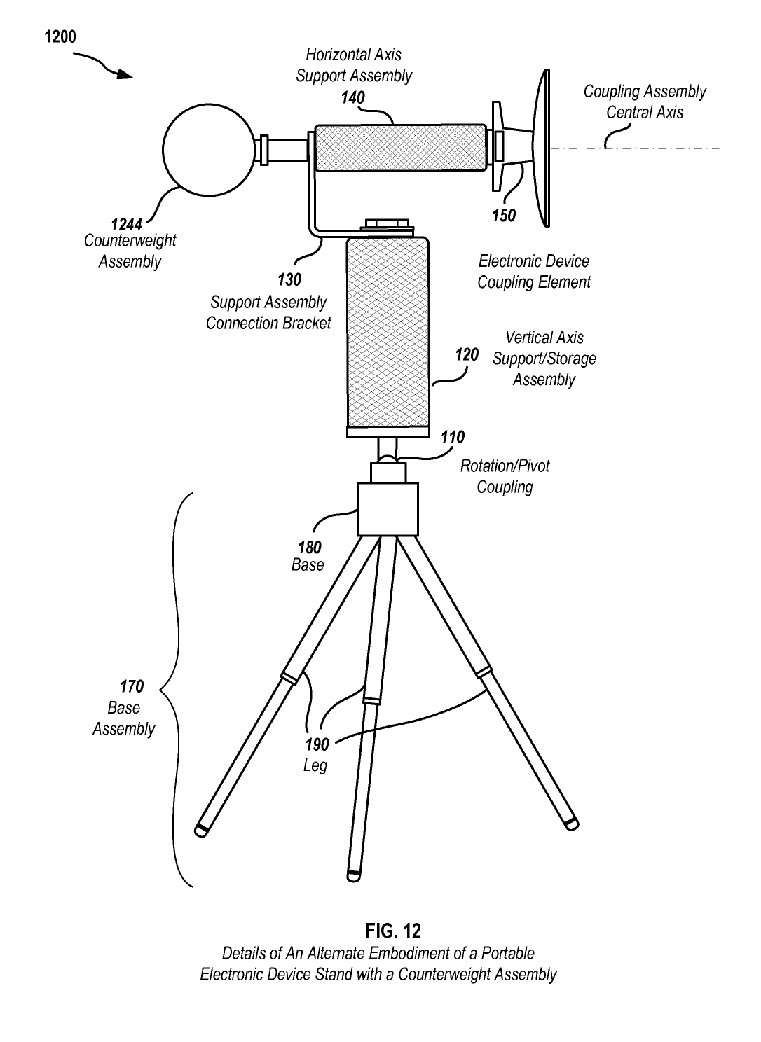

FIG. 12 illustrates details of another embodiment of a portable electronic device stand 1200, which may be configured similarly to the device stand of FIG. 1 or other device stands described herein. Device stand 1200 may include a counterweight assembly 1244 which may be coupled to the horizontal support assembly 140 (as shown) and/or to other elements of the stand (not shown) to counterbalance the stand/electronic device combination to better stabilize the system and avoid tipping, etc.

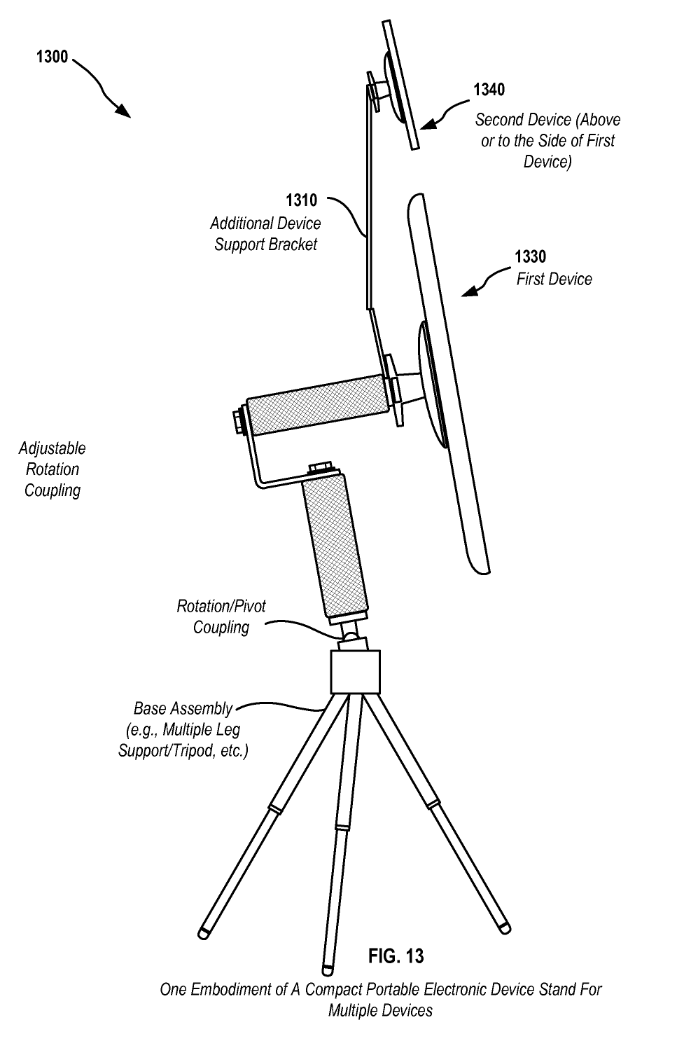

Some embodiments of portable device stands may include additional support structures for mechanically coupling other electronic or other devices or systems. For example, as shown in FIG. 13, a portable device stand 1300 may be configured similarly to the device stand embodiment of FIG. 1 but may further include a support mechanism for supporting additional devices either above the first device 1330 as shown or below or to the side of the first device 1330. For example, the support mechanism may include a support bracket 1310 and other coupling elements, such as rigid or flexible joints, hinges, knobs, and the like to allow a user to position a second device 1340 relative to the first device. The second device may be, for example, a cellular phone, PDA, music player, or other portable electronic device or other device or system.

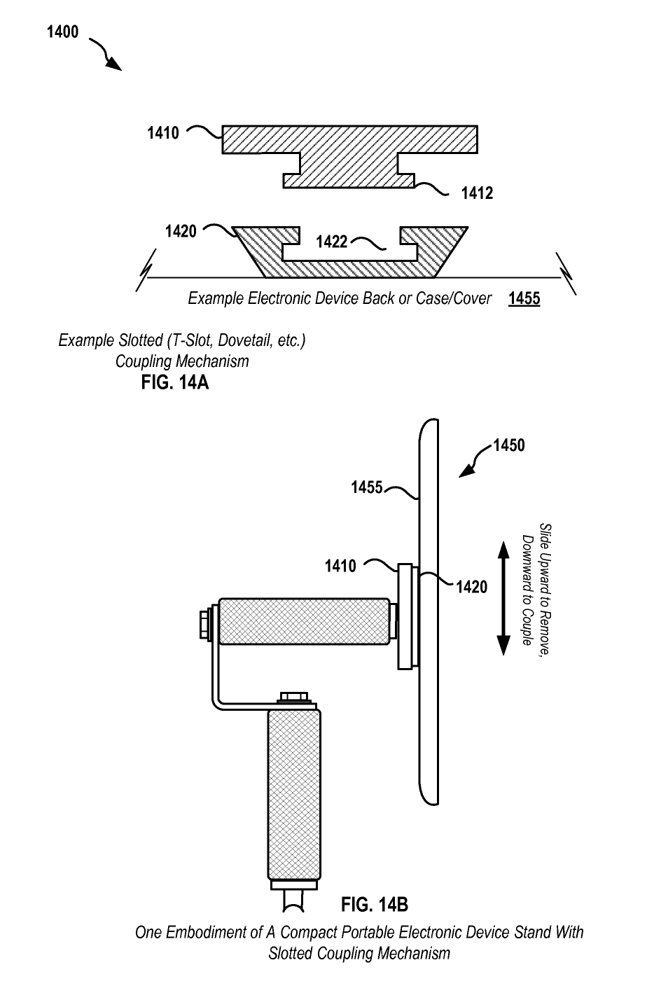

Some embodiments may include a slotted coupling mechanism in place of or in addition to the suction cups described previously herein. For example, a slotted coupling mechanism including a T-slot is shown in cross-section in FIG. 14A. In this embodiment, a male element 1410 including a raised t-shaped portion 1412 may slide within a corresponding channel 1422 of female slot element 1420. Other slot and raised configurations, such as dovetails, v-channels, and the like may be used in alternate embodiments. One of elements 1410 and 1420 may be coupled to the electronic device 1450 or a case or cover 1455, such as directly via adhesives, velco, or other attachment mechanisms, or may be formed into the back or case or cover. FIG. 14B illustrates one embodiment where a case 1455 surround electronic device 1450 and element 1450 is attached to the case 1455. Corresponding element 1410 is coupled to the stand such that it may slide into element 1420 (or vice versa) to install or remove the electronic device from the stand.

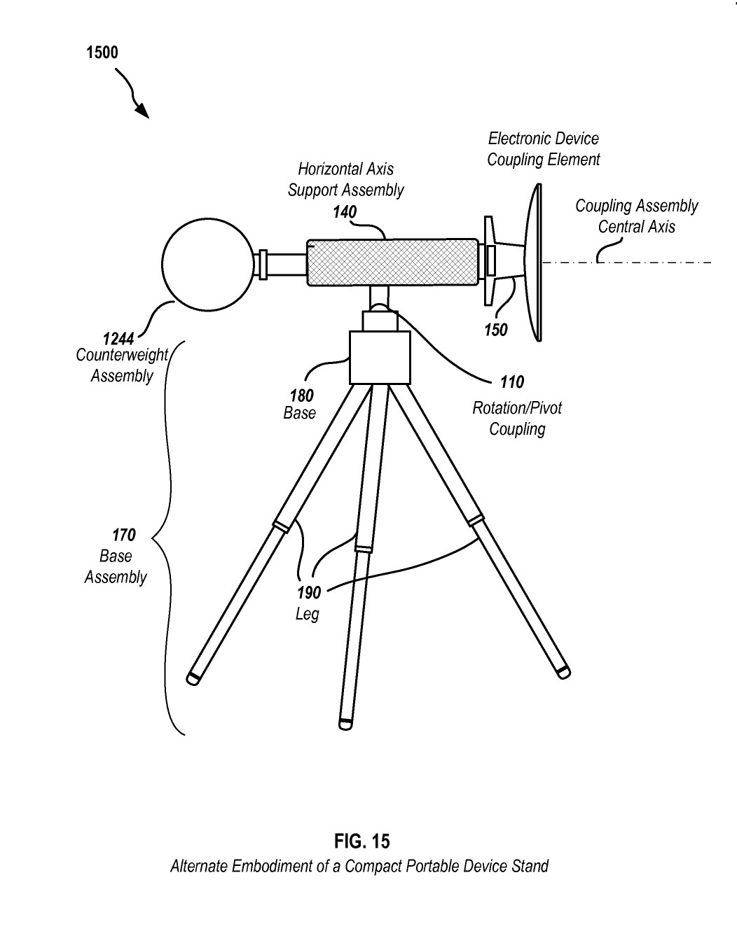

FIG. 15 illustrates details of another embodiment of a portable device stand 1500. This embodiment may be configured similarly to the embodiment of FIG. 1, or other embodiments described herein, but having a mechanical coupling directly between the base 180 or pivot point 110 and the horizontal axis support assembly or equivalent structure. For example, the horizontal support assembly or a similar or equivalent structure may be coupled directly to the base or two a tripod element (in embodiments including a trip as a bottom support structure such as shown in FIG. 1). In this configuration, the upper section including the horizontal axis support assembly and electronic device coupling element (e.g., suction cup, piezoelectric cup, hook and loop, slotted channel coupler, etc) are coupled either rigidly to the base and/or legs or via a pivot or movable coupling such as rotation/pivot coupling 110 or a similar or equivalent element. A counterweight, such as counterweigh 1244 as shown may optionally be included to provide counterbalance depending on the weight of the attached electronic device. In some embodiments the electronic device is a smaller-sized device such as a smart phone, PDA, small video display, or similar device, in which counterweighting may not be needed. Alternately, for embodiments configured for heavier devices, a counterweight as shown (or in other counterweight shapes, sizes, and configurations) may be used.

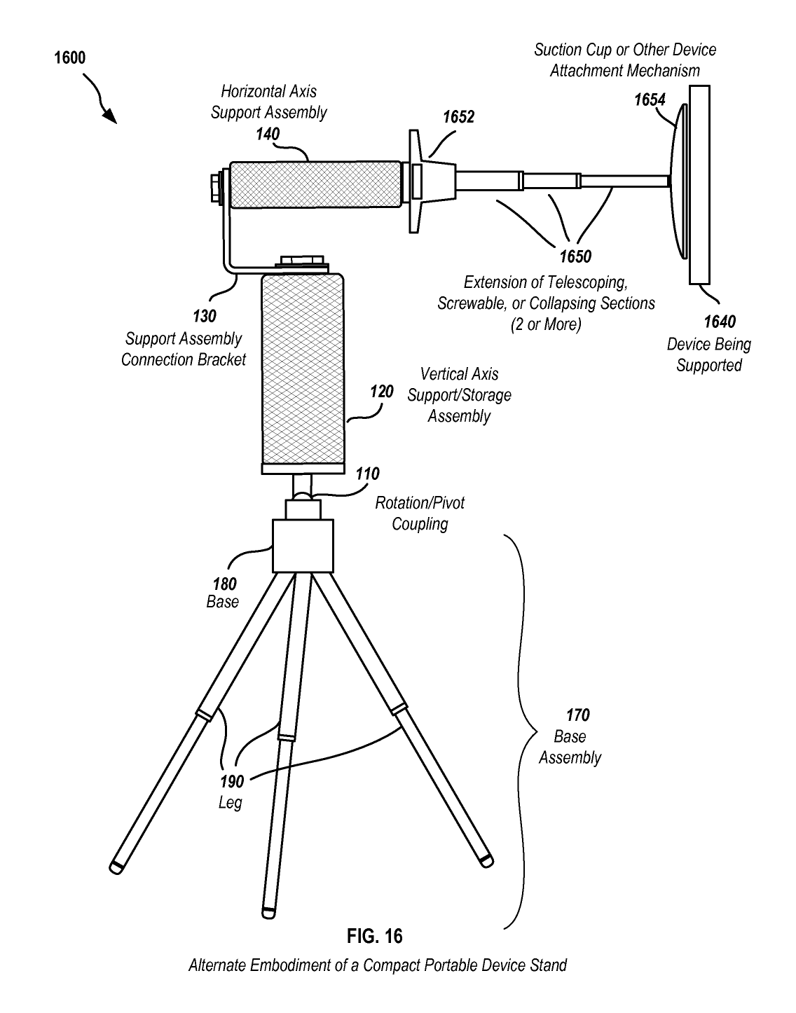

FIG. 16 illustrates details of yet another embodiment of a portable device stand 1600. In this embodiment, an adjustable expandable/contractible horizontal element 1650, such as a telescoping cantilever assembly or other multi-section screwable or collapsible section elements may be used in various embodiments. A suction cup 1654 or other device couping element such a described herein e.g., piezoelectric cup, hook and loop, slotted channel coupler, etc.) may be coupled to the adjustable horizontal element 1650 to support device 1640. In an exemplary embodiment, device 1640 may be a smaller-sized electronic device such as cellular phone, music player, and the like. A horizontal axis coupling element 1652 may be coupled to the adjustable horizontal element and may include threads, clips, pins, keys, or other mechanisms for coupling to the horizontal axis support assembly or other elements coupled to the base and legs. In some embodiments a counterweight structure (not shown in FIG. 16), such as is illustrated in FIG. 12 or 15, may optionally be used to counterbalance loading with the expandable horizontal element 1650 is extended.

Other attachment mechanisms may be used in various embodiments. For example, in some embodiments hook/loop type material, such as Velcro or similar materials may be used to couple the stand assembly to the portable device or a case or cover of the portable device.

In various embodiments as described herein, some or all of the lower elements of various stands may include weighting to aid support and avoid tipovers, etc. For example, at least the lower segments of legs in embodiments having telescoping leg sections may include filling or be made from a high density material to reduce the overall device center of gravity. In embodiments with multiple hollow leg segments the lower leg segment may be filled with a high density material to add weighting near the bottom of the stand (when placed in a normal upright position). Other embodiments may use separate weights or support structures to affix the stand to a surface on which it is placed, such as removable tethers, clips, straps, and the like.

Clearly, other embodiments and modifications of the disclosure herein may occur readily to those of ordinary skill in the art in view of these teachings. Therefore, the instant invention is to be limited only by the description herein and its equivalents, which include all such embodiments and modifications when viewed in conjunction with the above specification and accompanying drawing figures.

I claim:

1. A portable electronics device stand, comprising:
an electronics device coupling element;
a horizontal axis support element coupled to the device coupling element;
a vertical axis support element; and
a support element connection bracket coupled between the horizontal axis support element and the vertical axis support element.

2. The stand of claim 1, further comprising a base coupled to the vertical axis support element.

3. The stand of claim 1, wherein the electronic device coupling element is configured to rotate an attached device about a central axis.

4. The stand of claim 1, wherein the device coupling element includes a suction cup to attach the electronic device.

5. The stand of claim 1, wherein the device coupling element includes a threaded element to attach the electronic device.

6. The stand of claim 5, wherein the threaded element is a machine screw, wherein the machine screw is screwed into a corresponding threaded mount on the electronic device.

7. The stand of claim 1, wherein the horizontal axis support element, the vertical axis support element, or both support elements include one or more internal threaded holes.

8. The stand of claim 7, wherein the horizontal axis support element includes a threaded hole and wherein the support element connection bracket is attached to the horizontal axis support element with a machine screw screwed into the threaded hole.

9. The stand of claim 7, wherein the vertical axis support element includes a threaded hole and wherein the support element connection bracket is attached to the vertical axis support element with a machine screw screwed into the threaded hole.

10. The stand of claim 1, wherein the horizontal support element, the vertical support element, or both support elements are configured in a substantially cylindrical shape.

11. The stand of claim 1, wherein the horizontal support element, the vertical support element, or both support elements include a textured surface to facilitate gripping by a user.

12. The stand of claim 1, wherein the support element connection bracket is formed in substantially an L-shape.

13. The stand of claim 2, wherein the vertical axis support element includes an internal threaded hole and wherein the base is attached to the vertical axis support element using a corresponding threaded element screwed into the threaded hole.

14. The stand of claim 2, wherein the base comprises a tripod.

15. The stand of claim 2, wherein the base comprises a weight configured to support a predefined electronic device weight when the electronic device is attached to the electronics device coupling element.

16. The stand of claim 1, wherein the device coupling element includes an active material suction cup.

17. The stand of claim 16, wherein the active material is a piezoelectric material.

18. The stand of claim 4, further including a suction sensor to provide an output responsive to a suction condition.

19. The stand of claim 18, wherein the suction condition is a suction failure or pressure increase.

20. The stand of claim 1, wherein the device coupling element includes a slotted coupling mechanism.
